(19) United States
(12) Patent Application Publication
(10) Pub. No.: US 2024/0064473 A1
(43) Pub. Date: Feb. 22, 2024

(54) TRANSDUCER AND METHOD FOR MANUFACTURING SAME

(71) Applicant: ROHM CO., LTD., Kyoto-shi (JP)

(72) Inventors: Tatsuya SUZUKI, Kyoto-shi (JP); Yoshikazu FUJIMORI, Kyoto-shi (JP)

(21) Appl. No.: 18/487,662

(22) Filed: Oct. 16, 2023

Related U.S. Application Data
(63) Continuation of application No. PCT/JP2022/016714, filed on Mar. 31, 2022.

(30) Foreign Application Priority Data
Jun. 10, 2021 (JP) 2021-097554

(51) Int. Cl. H04R 17/02; H04R 7/04; H04R 7/18; H04R 31/00

(52) U.S. Cl. CPC H04R 17/02; H04R 7/04; H04R 7/18; H04R 31/003; H04R 2201/003

(57) ABSTRACT

A transducer includes a supporting body that has a cavity, a vibrating film that is provided facing the cavity and capable of vibrating in the facing direction, and a piezoelectric element at least a portion of which is formed on a front surface of the vibrating film at an opposite side to the cavity. The vibrating film has, at a portion of an outer peripheral edge of the vibrating film, a connection portion connected to the supporting body and the vibrating film has a non-line-symmetrical shape with respect to a straight line that extends along the front surface of the vibrating film and is orthogonal to a line joining both ends of the connection portion.

### CROSS REFERENCE TO RELATED APPLICATIONS

The present application is a bypass continuation of International Patent Application No. PCT/JP2022/016714, filed on Mar. 31, 2022, which corresponds to Japanese Patent Application No. 2021-097554 filed on Jun. 10, 2021 with the Japan Patent Office, and the entire disclosure of this application is incorporated herein by reference.

### TECHNICAL FIELD

The present disclosure relates to a transducer and a method for manufacturing the same.

### BACKGROUND ART

Transducers are known as one of various types of MEMS (micro electro mechanical systems) that are manufactured using semiconductor manufacturing processes. A MEMS transducer includes a piezoelectric element and a film body (vibrating film) that is driven by the piezoelectric element and is housed, for example, in a portable electronic equipment case, etc., as a speaker or a microphone (see Japanese Patent Application Publication No. 2011-31385).

The above and yet other objects, features, and effects of the present disclosure will become more apparent from the following description of the preferred embodiments made with reference to the attached drawings.

### BRIEF DESCRIPTION OF DRAWINGS

FIG. 1 is an illustrative plan view of a transducer according to a preferred embodiment of the present disclosure.

FIG. 2 is an illustrative plan view of the transducer according to the preferred embodiment of the present disclosure and is a plan view with which a protective substrate and a passivation film are omitted.

FIG. 3 is an illustrative sectional view taken along line III-III of FIG. 1.

FIG. 4 is an enlarged illustrative plan view showing a vibrating film.

FIG. 5A is an illustrative sectional view showing a portion of a manufacturing process of the transducer of FIG. 1.

FIG. 5B is an illustrative sectional view showing a step subsequent to that of FIG. 5A.

FIG. 5C is an illustrative sectional view showing a step subsequent to that of FIG. 5B.

FIG. 5D is an illustrative sectional view showing a step subsequent to that of FIG. 5C.

FIG. 5E is an illustrative sectional view showing a step subsequent to that of FIG. 5D.

FIG. 5F is an illustrative sectional view showing a step subsequent to that of FIG. 5E.

FIG. 5G is an illustrative sectional view showing a step subsequent to that of FIG. 5F.

FIG. 5H is an illustrative sectional view showing a step subsequent to that of FIG. 5G.

FIG. 6A is an illustrative plan view showing a portion of a manufacturing process of the transducer of FIG. 1.

FIG. 6B is an illustrative plan view showing a step subsequent to that of FIG. 6A.

FIG. 6C is an illustrative plan view showing a step subsequent to that of FIG. 6B.

FIG. 6D is an illustrative plan view showing a step subsequent to that of FIG. 6C.

FIG. 6E is an illustrative plan view showing a step subsequent to that of FIG. 6D.

FIG. 6F is an illustrative plan view showing a step subsequent to that of FIG. 6E.

FIG. 6G is an illustrative plan view showing a step subsequent to that of FIG. 6F.

FIG. 7 is an enlarged illustrative plan view showing a modification example of the vibrating film.

FIG. 8 is an enlarged illustrative plan view showing another modification example of the vibrating film.

FIG. 9 is an enlarged illustrative plan view showing yet another modification example of the vibrating film.

### DESCRIPTION OF EMBODIMENTS

A preferred embodiment of the present disclosure provides a transducer including a supporting body that has a cavity, a vibrating film that is provided facing the cavity and capable of vibrating in the facing direction, and a piezoelectric element at least a portion of which is formed on a front surface of the vibrating film at an opposite side to the cavity and where the vibrating film has, at a portion of an outer peripheral edge of the vibrating film, a connection portion connected to the supporting body and the vibrating film has a non-line-symmetrical shape with respect to a straight line that extends along the front surface of the vibrating film and is orthogonal to a line joining both ends of the connection portion.

With this arrangement, a standing wave that is generated due to vibration of the vibrating film can be suppressed.

In the preferred embodiment of the present disclosure, the outer peripheral edge of the vibrating film does not include parallel rectilinear portions that face and are parallel to each other in plan view.

In the preferred embodiment of the present disclosure, the vibrating film is, in plan view, of a polygonal shape having a plurality of sides and the plurality of sides do not include sides that face and are parallel to each other.

In the preferred embodiment of the present disclosure, the supporting body includes a supporting substrate that has the cavity and a frame portion that is formed on the supporting substrate and is formed such as to surround the cavity, the connection portion of the vibrating film is connected to the frame portion, and a slit that is in communication with the cavity is formed between the frame portion and an outer peripheral edge of the vibrating film excluding the connection portion.

In the preferred embodiment of the present disclosure, a cantilever is formed that includes the vibrating film and a portion of the piezoelectric element disposed on the vibrating film and has a fixed end and a free end.

In the preferred embodiment of the present disclosure, the piezoelectric element includes a lower electrode at least a portion of which is disposed on the vibrating film, a piezoelectric film that is formed on the lower electrode, and an upper electrode that is formed on the piezoelectric film.

In the preferred embodiment of the present disclosure, a hydrogen barrier film that covers the front surface of the vibrating film and a front surface of the piezoelectric element, an interlayer insulating film that is selectively formed on the hydrogen barrier film, an upper wiring that is formed on the interlayer insulating film and has one end connected to the upper electrode and another end extending to an outside of the cavity, a lower wiring that is formed on the interlayer insulating film and has one end connected to the lower electrode and another end extending to the outside of the cavity, and a passivation film that is formed on the interlayer insulating film and covers the upper wiring and the lower wiring are included.

In the preferred embodiment of the present disclosure, a protective substrate that is fixed to the supporting body such as to cover at least a portion of the cantilever is included.

A preferred embodiment of the present disclosure provides a method for manufacturing transducer including a step of forming a piezoelectric element on a vibrating film formation layer that is formed on a supporting substrate, a vibrating film forming step of forming a slit penetrating through the vibrating film formation layer in a thickness direction to form, in the vibrating film formation layer, a vibrating film and a frame portion that surrounds the vibrating film and with which a portion is connected to a portion of the vibrating film, and a step of etching the supporting substrate from a cavity formation planned region of a rear surface of the supporting substrate that is a surface at an opposite side to the vibrating film formation layer to form, in a region facing the vibrating film, a cavity that is in communication with the slit, and where if the portion of the vibrating film connected to the frame portion is a connection portion, the vibrating film formed in the vibrating film forming step has a non-line-symmetrical shape with respect to a straight line that extends along a front surface of the vibrating film and is orthogonal to a line joining both ends of the connection portion.

With this manufacturing method, a transducer with which a standing wave generated due to vibration of the vibrating film can be suppressed can be manufactured.

In the preferred embodiment of the present disclosure, an outer peripheral edge of the vibrating film does not include parallel rectilinear portions that face and are parallel to each other in plan view.

In the preferred embodiment of the present disclosure, the vibrating film is, in plan view, of a polygonal shape having a plurality of sides and the plurality of sides do not include sides that face and are parallel to each other.

Preferred embodiments of the present disclosure shall be described in detail below with reference to the attached drawings.

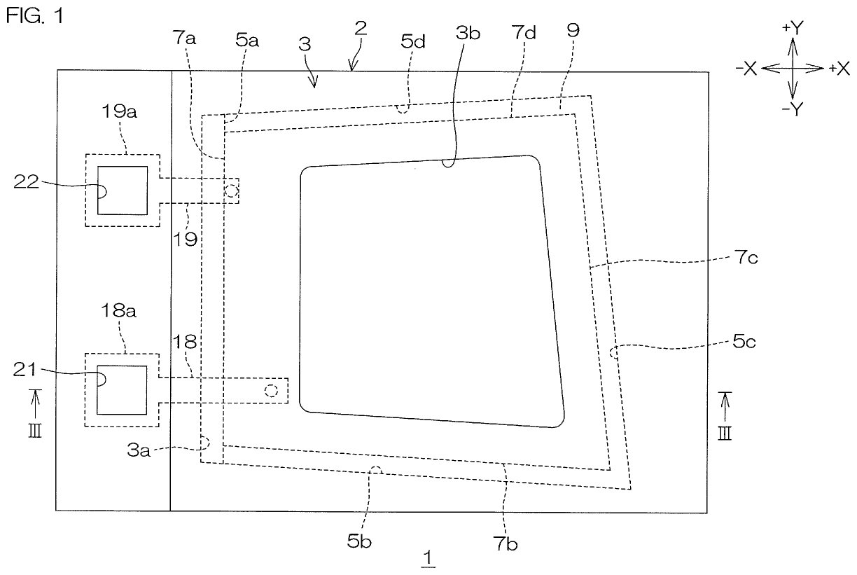

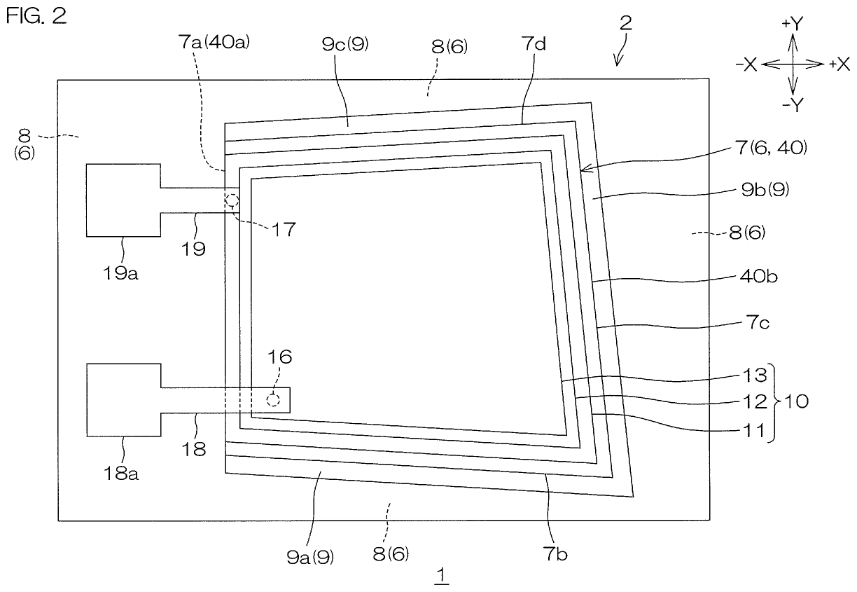

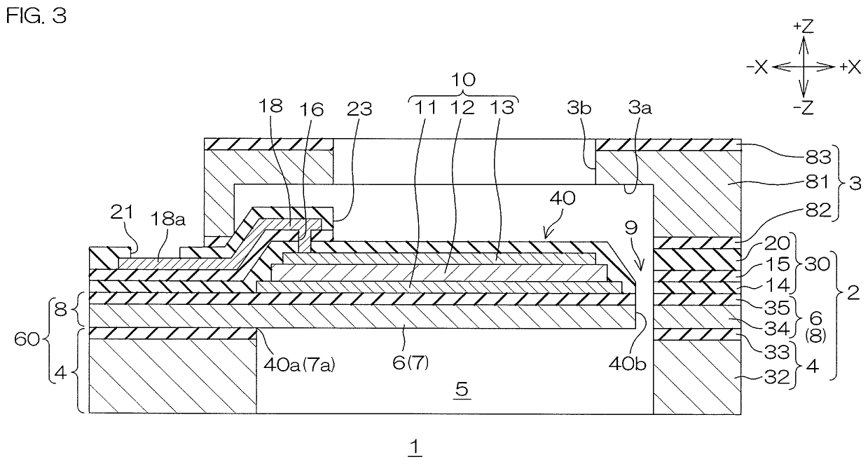

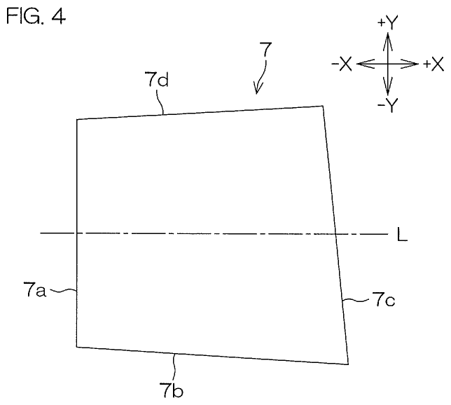

FIG. 1 is an illustrative plan view of a transducer according to a preferred embodiment of the present disclosure. FIG. 2 is an illustrative plan view of the transducer according to the preferred embodiment of the present disclosure and is a plan view with which a protective substrate and a passivation film are omitted. FIG. 3 is an illustrative sectional view taken along line III-III of FIG. 1. FIG. 4 is an enlarged illustrative plan view showing a vibrating film.

For convenience of description, a +X direction, a −X direction, a +Y direction, a −Y direction, a +Z direction, and a −Z direction shown in FIG. 1 to FIG. 4 are used at times in the following description. The +X direction is a predetermined direction along a front surface of a supporting substrate 4 in plan view and the +Y direction is a direction along the front surface of the supporting substrate 4 and is a direction that is orthogonal to the +X direction in plan view. The +Z direction is a direction along a thickness of the supporting substrate 4 and is a direction that is orthogonal to the +X direction and the +Y direction.

The −X direction is a direction opposite to the +X direction. The −Y direction is a direction opposite to the +Y direction. The −Z direction is a direction opposite to the +Z direction. The +X direction and the −X direction shall be referred to simply as the “X direction” when referred to collectively. The +Y direction and the −Y direction shall be referred to simply as the “Y direction” when referred to collectively. The +Z direction and the −Z direction shall be referred to simply as the “Z direction” when referred to collectively.

A transducer 1 includes a substrate assembly 2 and the protective substrate 3. The substrate assembly 2 includes the supporting substrate 4, a vibrating film formation layer 6, and a piezoelectric element 10.

In plan view, the supporting substrate 4 is of a quadrilateral shape and has two sides that face each other at an interval in the X direction and are parallel to the Y direction and two sides that face each other at an interval in the Y direction and are parallel to the X direction. The supporting substrate 4 is made, for example, from a portion of an SOI (silicon on insulator) substrate. Specifically, the SOI substrate includes a silicon (Si) substrate 32 as a supporting layer, an oxide film layer 33 as a BOX layer formed on a front surface of the preceding, and a silicon (Si) layer 34 as an active layer formed on a front surface of the preceding. In this preferred embodiment, a silicon oxide (SiO₂) film 35 is formed on a front surface of the silicon layer 34. The supporting substrate 4 includes, among the above, the silicon substrate 32 and the oxide film layer 33 formed on the front surface thereof. A thickness of the supporting substrate 4 is approximately 380 μm.

The supporting substrate 4 has a cavity (hollow space) 5 that is formed by a penetrating hole penetrating through in the thickness direction (Z direction). In plan view, the cavity 5 is of a quadrilateral shape and has first to fourth sides 5a to 5d. The first side 5a is formed parallel to the Y direction in plan view. The third side 5c faces the first side 5a and is disposed at the +Y side with respect to the first side 5a. The third side 5c extends in an oblique direction with respect to the Y direction. More specifically, the third side 5c extends in an obliquely −X-ward direction toward the +Y direction. A length of the third side 5c is longer than a length of the first side 5a. A −Y side end of the third side 5c is positioned further to the −Y direction side than a −Y side end of the first side 5a. A +Y side end of the third side 5c is positioned further to the +Y direction side than a +Y side end of the first side 5a.

The second side 5b connects the −Y side end of the first side 5a and the −Y side end of the third side 5c. The fourth side 5d connects the +Y side end of the first side 5a and the +Y side end of the third side 5c.

The vibrating film formation layer 6 is formed on the supporting substrate 4. The vibrating film formation layer 6 is constituted of a laminated film in which the silicon layer 34 and the silicon oxide layer 35 are laminated in that order from the supporting substrate 4 side. A film thickness of the silicon layer 34 is approximately 20 un and a film thickness of the silicon oxide film 35 is approximately 0.5 μm.

In plan view, the vibrating film formation layer 6 includes a vibrating film 7 that faces the cavity 5 and a frame portion 8 that is formed such as to surround the cavity 5. The vibrating film 7 has, at a portion of an outer peripheral edge of the vibrating film 7, a connection portion (a first side to be described below) 7a that is connected to the frame portion 8. A slit 9 that is in communication with the cavity 5 is formed between the frame portion 8 and an outer edge of the vibrating film 7 excluding the connection portion 7a.

In this preferred embodiment, the vibrating film 7 is, in plan view, of a quadrilateral shape substantially similar to the cavity 5. The vibrating film 7 has the first side (connection portion) 7a oriented along the first side 5a of the cavity 5, a second side 7b oriented along the second side 5b of the cavity 5, a third side 7c oriented along the third side 5c of the cavity 5, and a fourth side 7d oriented along the fourth side 5d of the cavity 5. The frame portion 8 has a rectangular annular shape in plan view. The connection portion 7a is matched (in conformity) with an intermediate portion of the first side 5a of the cavity 5 in plan view.

In this preferred embodiment, the vibrating film 7 has a non-line-symmetrical shape with respect to a straight line L (see FIG. 4) that extends along a front surface of the vibrating film 7 and is orthogonal to a line joining both ends of the connection portion 7a. Also, in this preferred embodiment, the four sides 7a to 7d of the vibrating film 7 do not include sides that face and are parallel to each other.

In a manufacturing process, the slit 9 is formed before the cavity 5 is formed in the supporting substrate 4. In a step in which the slit 9 is formed, the slit 9 is formed such that, from a front surface of a hydrogen barrier film 14 to be described later that is formed on the vibrating film formation layer 6, it penetrates continuously through the hydrogen barrier film 14 and the vibrating film 7 and reaches the oxide film layer 33.

In plan view, the slit 9 is constituted of a first portion 9a oriented along the second side 5b of the cavity 5, a second portion 9b oriented along the third side 5c of the cavity 5, and a third portion 9c oriented along the fourth side 5d of the cavity 5. The second portion 9b joins a +X direction side end of the first portion 9a and a +X direction side end of the third portion 9c.

An outer edge of the first portion 9a is substantially matched with the second side 5b of the cavity 5 in plan view. Similarly, an outer edge of the second portion 9b is substantially matched with the third side 5c of the cavity 5 in plan view. An outer edge of the third portion 9c is substantially matched with the fourth side 5d of the cavity 5 in plan view.

The connection portion 7a of the vibrating film 7 can be defined as follows. That is, a portion of the outer peripheral edge of the vibrating film 7 that corresponds to a portion of an outer peripheral edge of the cavity 5 between both ends of the slit 9 is the connection portion 7a. The vibrating film 7 is mainly deformable in the thickness direction (Z direction) of the supporting substrate 4.

In this preferred embodiment, a supporting body 60 is constituted by the supporting substrate 4 and the frame portion 8 and the vibrating film 7 is cantilever-supported by the supporting body 60. The supporting body 60 is an example of a “supporting body” of the present invention.

The piezoelectric element 10 is formed on the vibrating film formation layer 6 such that at least a portion thereof is disposed on the vibrating film 7. The piezoelectric element 10 includes a lower electrode 11 that is formed on the vibrating film formation layer 6, a piezoelectric film 12 that is formed on the lower electrode 11, and an upper electrode 13 that is formed on the piezoelectric film 12. In this preferred embodiment, an entirety of the piezoelectric element 10 is disposed on the vibrating film 7. The piezoelectric element 10 may be constituted of a main portion that is disposed on the vibrating film 7 and an extension portion that crosses the connection portion 7a from the main portion and extends onto the frame portion 8.

The lower electrode 11 and the upper electrode 13 are constituted, for example, of platinum, molybdenum, iridium, titanium, or other metal thin films having conductivity. A film thickness of the lower electrode 11 is approximately 200 μm and a film thickness of the upper electrode 13 is approximately 80 μm.

The piezoelectric film 12 is constituted, for example, of lead zirconate titanate (PZT). The piezoelectric film 12 may instead be constituted of aluminum nitride (AlN), zinc oxide (ZnO), lead titanate (PbTiO₃), etc. A film thickness of the piezoelectric film 12 is approximately 2 pam.

The hydrogen barrier film 14 is formed on the vibrating film formation layer 6 such as to cover the piezoelectric element 10. The hydrogen barrier film 14 is constituted, for example, of Al₂O₃(alumina). A thickness of the hydrogen barrier film 14 is approximately 80 nm. The hydrogen barrier film 14 is provided to prevent characteristics degradation of the piezoelectric film 12 due to hydrogen reduction.

An interlayer insulating film 15 is laminated on the hydrogen barrier film 14. The interlayer insulating film 15 is constituted, for example, of a film (TEOS film) that contains tetraethoxysilane (TEOS). A thickness of the interlayer insulating film 15 is approximately 1 μm. An upper wiring 18 and a lower wiring 19 are formed on the interlayer insulating film 15. The upper wiring 18 and the lower wiring 19 extend in parallel to each other in the X direction at an interval in the Y direction. These wirings 18 and 19 may be constituted of a metal material that contains Al (aluminum). A thickness of these wirings 18 and 19 is approximately 1 pam.

A +X side end portion of the upper wiring 18 is disposed above a −X side end portion of the upper electrode 13. A contact hole 16 that penetrates continuously through the hydrogen barrier film 14 and the interlayer insulating film 15 is formed between the upper wiring 18 and the upper electrode 13. The +X side end portion of the upper wiring 18 enters into the contact hole 16 and is connected to the upper electrode 13 inside the contact hole 16. The upper wiring 18 extends in the −X direction from above the upper electrode 13. An upper pad portion 18a of wide width is formed at a −X side end portion of the upper wiring 18. The upper pad portion 18a is disposed on the frame portion 8 at an outside of the cavity 5.

A +X side end portion of the lower wiring 19 is disposed above a −X side end portion of the lower electrode 11. A contact hole 17 that penetrates continuously through the hydrogen barrier film 14 and the interlayer insulating film 15 is formed between the lower wiring 19 and an extension portion of the lower electrode 11. The +X side end portion of the lower wiring 19 enters into the contact hole 17 and is connected to the lower electrode 11 inside the contact hole 17. The lower wiring 19 extends in the −X direction from above the lower electrode 11. A lower pad portion 19a of wide width is formed at a −X side end portion of the lower wiring 19. The lower pad portion 19a is disposed on the frame portion 8 at the outside of the cavity 5.

A passivation film 20 is formed on the interlayer insulating film 15 such as to cover the upper wiring 18 and the lower wiring 19. The passivation film 20 is constituted, for example, of a film (TEOS film) that contains tetraethoxysilane (TEOS). A thickness of the passivation film 20 is approximately 0.5 μm. An upper pad opening 21 that exposes a portion of the upper pad portion 18a and a lower pad opening 22 that exposes a portion of the lower pad portion 19a are formed in the passivation film 20.

In the following, the hydrogen barrier film 14, the interlayer insulating film 15, and the passivation film 20 may be referred to collectively at times as an insulating film 30.

A cantilever 40 of quadrilateral shape in plan view is constituted by the vibrating film 7 and members formed on the vibrating film 7. The cantilever 40 includes the vibrating film 7, the portion of the piezoelectric element 10 disposed on the vibrating film 7 (in this preferred embodiment, the entirety of the piezoelectric element 10), and the insulating film 30 on the vibrating film 7. In this preferred embodiment, the cantilever 40 also includes the wiring disposed on the vibrating film 7. The cantilever 40 has a fixed end 40a at an edge portion (the connection portion 7a) of the first side 5a of the cavity 5 and this fixed end 40a is supported by the supporting substrate 4.

In plan view, the cantilever 40 has, in a vicinity of the third side 5c of the cavity 5, a free end 40b at a position separated by just a predetermined distance toward an inside of the cavity 5 from the third side 5c. In plan view, a side of the cantilever 40 at the second side 5b side of the cavity 5 is separated toward the inside of the cavity 5 from the second side 5b. In plan view, a side of the cantilever 40 at the fourth side 5d side of the cavity 5 is separated toward the inside of the cavity 5 from the fourth side 5d.

The protective substrate 3 is constituted of a silicon substrate 81 with, for example, silicon oxide films 82 and 83 formed on a lower surface and an upper surface. The protective substrate 3 is disposed on the substrate assembly 2 such as to cover at least a portion of the cantilever 40 (in this preferred embodiment, an entirety of the cantilever 40). The protective substrate 3 is bonded to the frame portion 8 via an adhesive (not shown). The protective substrate 3 has a housing recess 3a for housing the cantilever 40 at a facing surface that faces the substrate assembly 2. In plan view, the facing recess 3a is disposed directly above a region that includes the cavity 5 and the piezoelectric element 10. A penetrating hole 3b for putting the housing recess 3a in communication with an external space is formed in an upper wall of the housing recess 3a of the protective substrate 3.

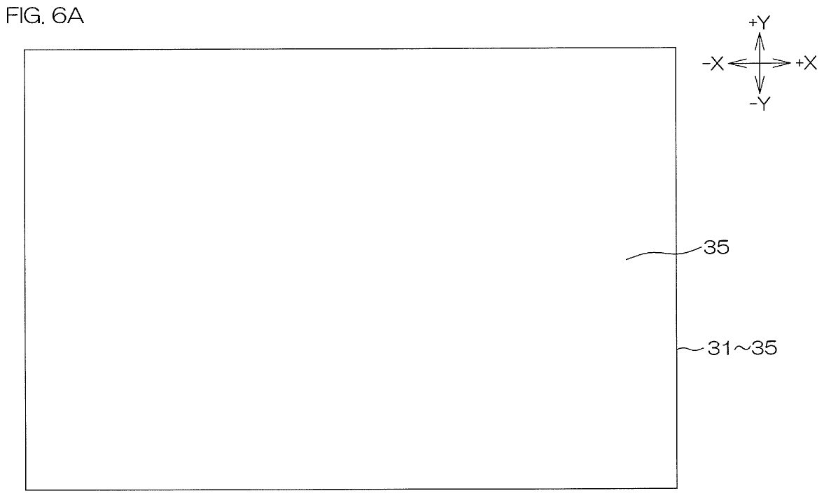

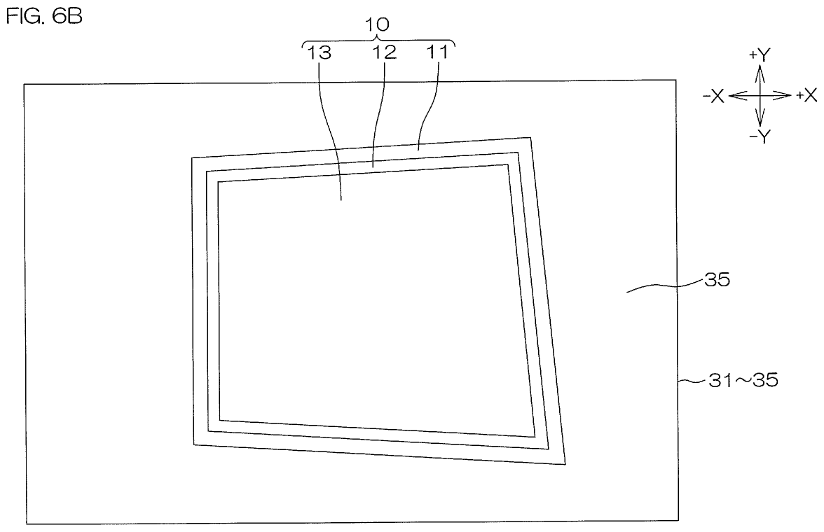

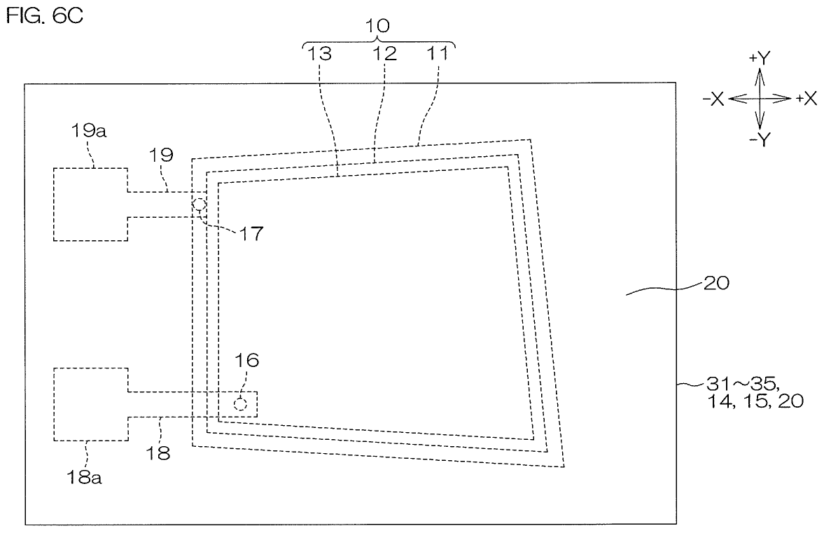

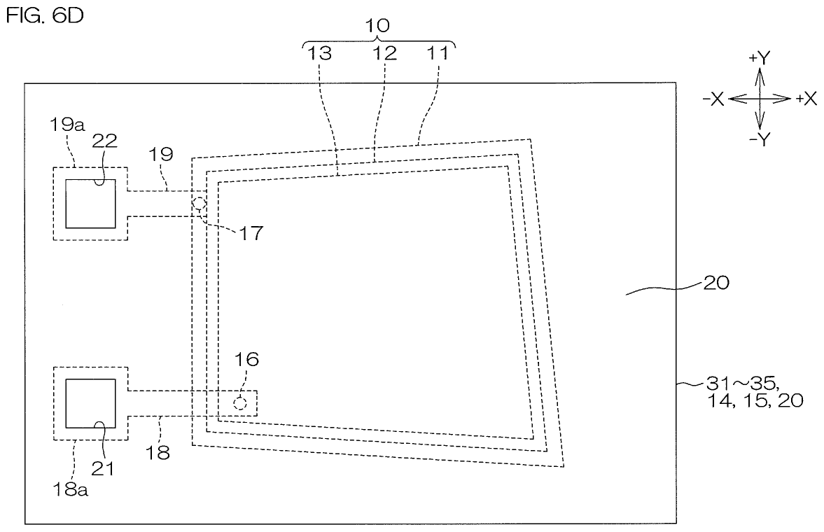

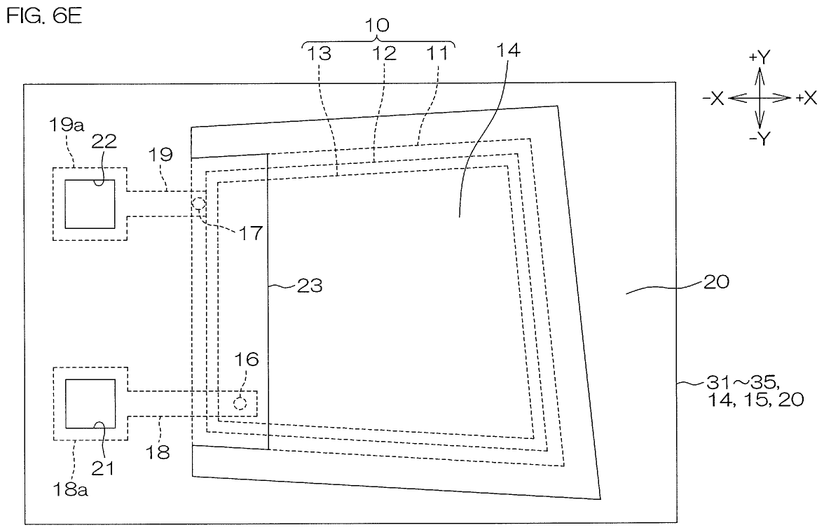

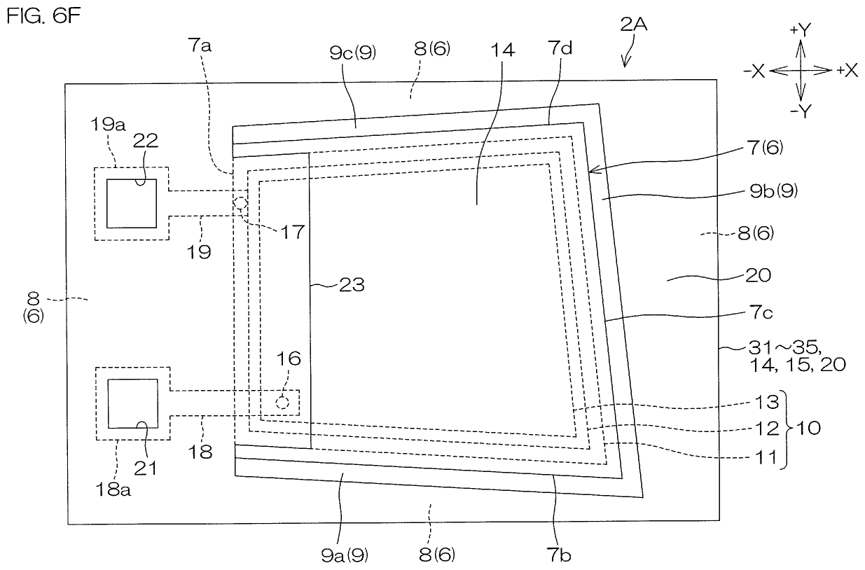

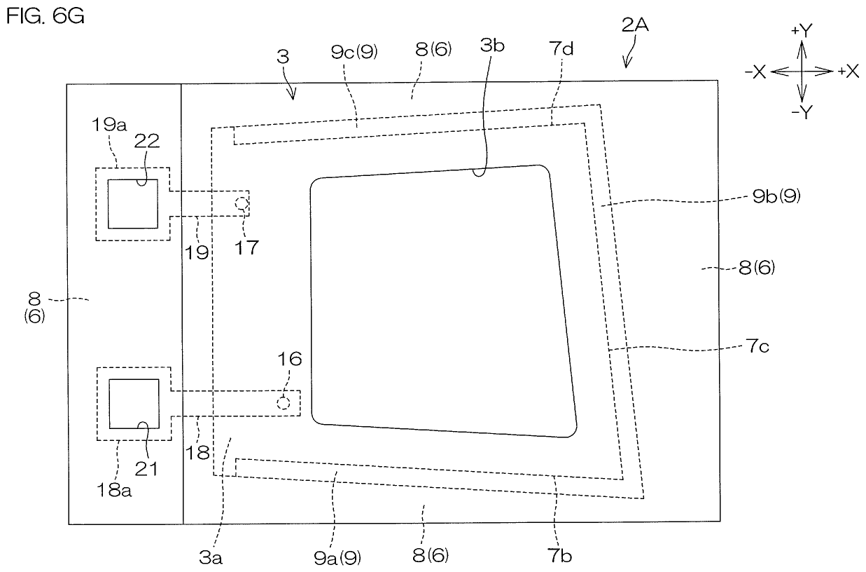

In plan view, the interlayer insulating film 15 and the passivation film 20 are formed across substantially an entire area of an outer region of the housing recess 3a of the protective substrate 3. However, in this region, the pad openings 21 and 22 are formed in the passivation film 20. In an inner region of the housing recess 3a of the protective substrate 3, the interlayer insulating film 15 and the passivation film 20 are formed just at an end portion (hereinafter referred to as a “wiring region”) at the −X side at which the upper wiring 18 and the lower wiring 19 are present. In other words, in the inner region of the housing recess 3a of the protective substrate 3, an opening 23 (see also FIG. 6E) is formed in the interlayer insulating film 15 and the passivation film 20 in a region excluding the wiring region. In the wiring region, the contact holes 16 and 17 are formed in the interlayer insulating film 15.

If, for example, the transducer 1 is used as a speaker, when a voltage is applied between the lower electrode 11 and the upper electrode 13, the piezoelectric film 12 deforms due to an inverse piezoelectric effect. The cantilever 40 thereby deforms with the fixed end 40a as a fulcrum. When a voltage that is in accordance with an audio signal is applied continuously between the lower electrode 11 and the upper electrode 13, the cantilever 40 vibrates such that the free end 40b of the cantilever 40 moves reciprocally in the Z direction. Due to such vibration of the cantilever 40, air surrounding the cantilever 40 vibrates and a sound wave is generated. The sound wave propagates to the external space via the penetrating hole 3b of the protective substrate 3.

When the cantilever 40 (vibrating film 7) vibrates, a plate wave is generated in the vibrating film 7. The plate wave may reflect at an end surface of the vibrating film 7 and generate a standing wave. In this preferred embodiment, the vibrating film 7 has the non-line-symmetrical shape with respect to the straight line L that extends along the front surface of the vibrating film 7 and is orthogonal to the line joining both ends of the connection portion 7a. Thereby, the plate waves reflected at the end surface of the vibrating film 7 cancel each other out easily and the standing wave can be suppressed. Also, with this preferred embodiment, since the outer peripheral edge of the vibrating film 7 does not include parallel rectilinear portions that face and are parallel to each other in plan view, the standing wave can be suppressed more effectively.

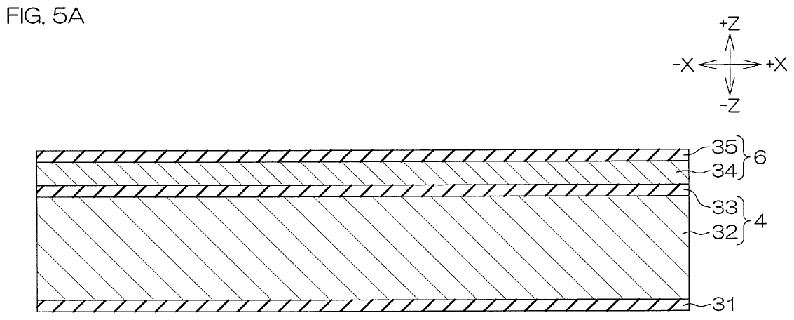

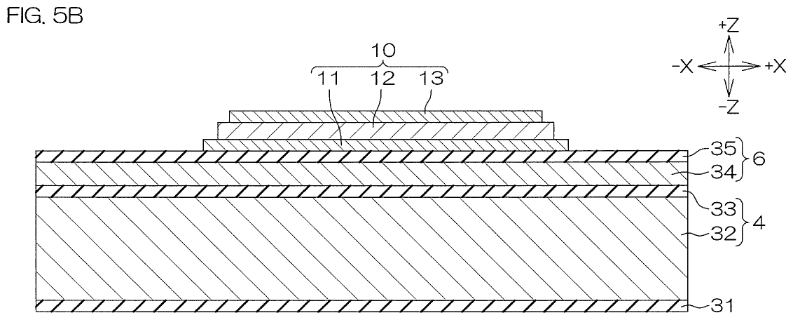

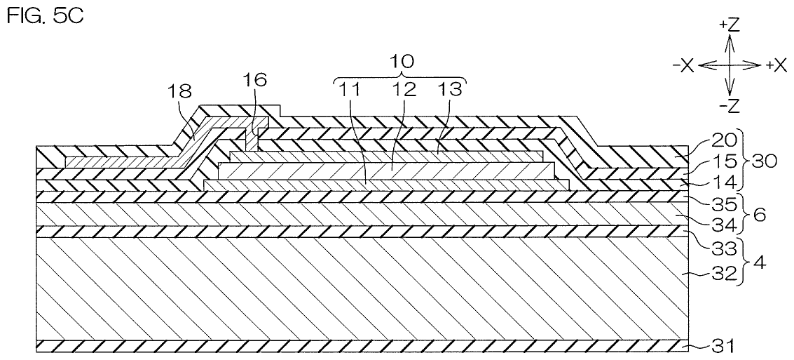

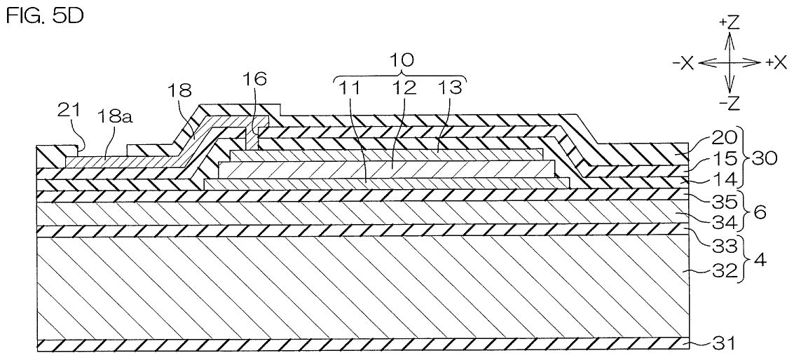

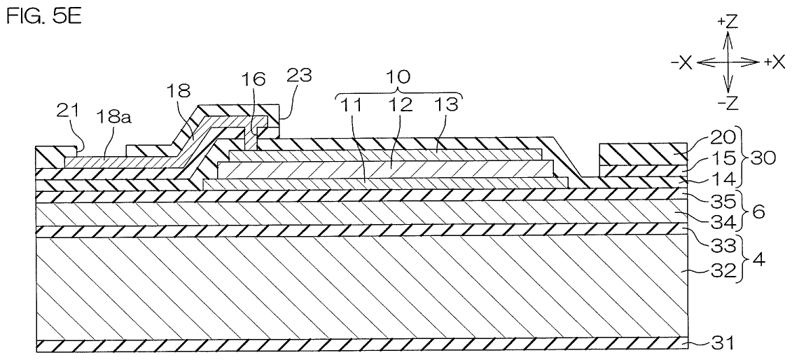

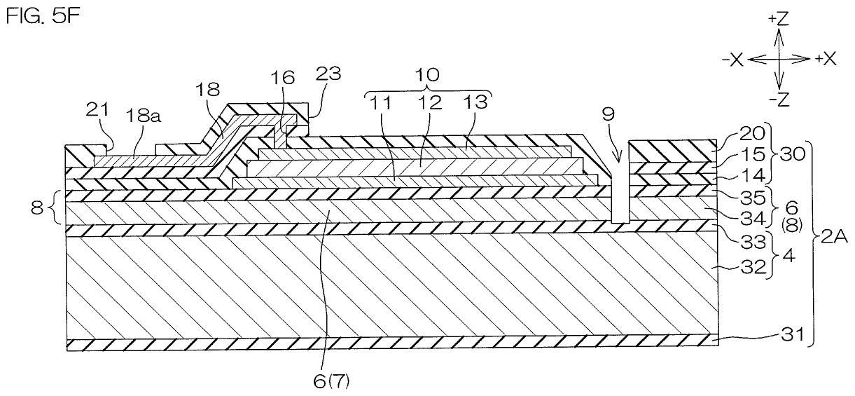

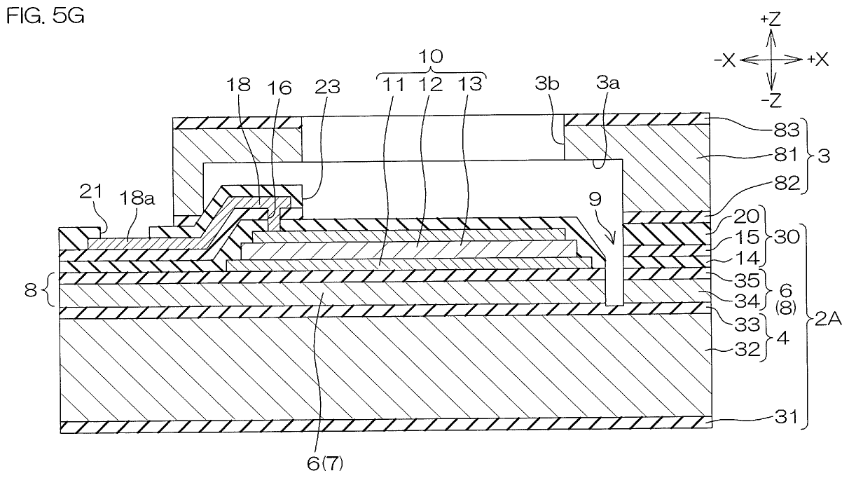

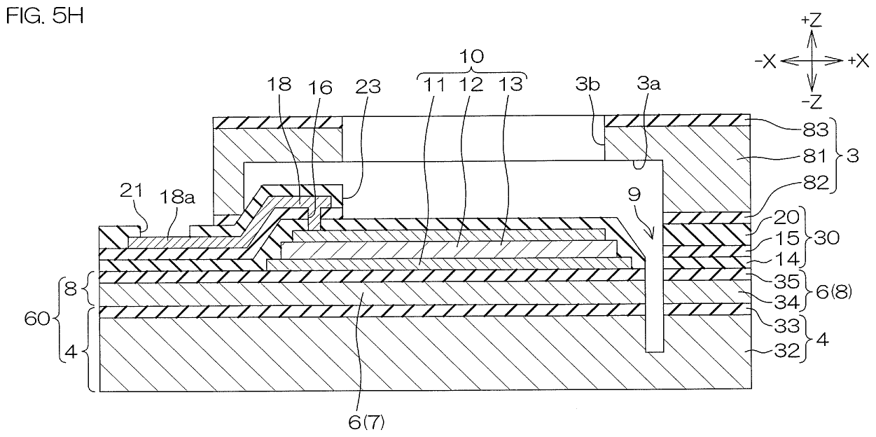

FIG. 5A to FIG. 5H are illustrative sectional views sequentially showing a manufacturing process of the transducer 1 of FIG. 1. FIG. 6A to FIG. 6G are illustrative plan views sequentially showing the manufacturing process of the transducer 1.

As shown in FIG. 5A and FIG. 6A, a thermal oxidation treatment is performed on an SIO substrate. The SIO substrate includes the silicon substrate 32, the oxide film layer 33 formed on the front surface of the preceding, and the silicon layer 34 formed on the front surface of the preceding. By the thermal oxidation treatment, the silicon oxide film 35 is formed on the front surface (+Z side surface) of the silicon layer 34 at an opposite side to the oxide film layer 33 and a silicon oxide film 31 is formed on a surface (−Z side surface) of the silicon substrate 32 at an opposite side to the oxide film layer 33. The supporting substrate 4 is constituted by the silicon substrate 32 and the oxide film layer 33 and the vibrating film formation layer 6 is constituted by the silicon layer 34 and the silicon oxide film 35.

Next, as shown in FIG. 5B and FIG. 6B, a lower electrode film that is a material film of the lower electrode 11, a piezoelectric material film that is a material film of the piezoelectric film 12, and an upper electrode film that is a material film of the upper electrode 13 are formed in that order on the silicon oxide film 35. By the upper electrode film, the piezoelectric material film, and the lower electrode film being patterned, for example in that order by photolithography and etching, the upper electrode 13, the piezoelectric film 12, and the lower electrode 11 are formed. The piezoelectric element 10 is thereby formed on the silicon oxide film 35.

Next, as shown in FIG. 5C and FIG. 6C, the hydrogen barrier film 14 that covers an exposed surface of the silicon oxide film 35 and an exposed surface of the piezoelectric element 10 is formed on the silicon oxide film 35. The hydrogen barrier film 14 is constituted, for example, of an alumina (Al₂O₃) film. The interlayer insulating film 15 is formed on an entire surface on the hydrogen barrier film 14. The contact holes 16 and 17 are then formed by etching the hydrogen barrier film 14 and the interlayer insulating film 15 continuously.

Next, a wiring film that is a material film of the upper wiring 18 and the lower wiring 19 is formed on the interlayer insulating film 15 including interiors of the contact holes 16 and 17. Thereafter, the upper wiring 18 and the lower wiring 19 are formed by the wiring film being patterned by photolithography and etching. The passivation film 20 is then formed on the interlayer insulating film 15 such as to cover the upper wiring 18 and the lower wiring 19. The interlayer insulating film 15 and the passivation film 20 are constituted, for example, of films (TEOS films) containing tetraethoxysilane (TEOS).

Next, as shown in FIG. 5D and FIG. 6D, the upper pad opening 21 that exposes a portion of the upper pad portion 18a and the lower pad opening 22 that exposes a portion of the lower pad portion 19a are formed in the passivation film 20 by photolithography and etching.

Next, as shown in FIG. 5E and FIG. 6E, the opening 23 is formed in the interlayer insulating film 15 and the passivation film 20 by photolithography and etching.

Next, as shown in FIG. 5F and FIG. 6F, the slit 9 that penetrates continuously through the hydrogen barrier film 14 and the vibrating film formation layer 6 (the silicon oxide film 35 and the silicon layer 34) and reaches the oxide film layer 33 is formed by photolithography and etching.

By the slit 9 being formed, the frame portion 8 constituted of a peripheral edge portion of the vibrating film formation layer 6 and the vibrating film 7 that is constituted of a central portion of the vibrating film formation layer 6 and with which a portion of the outer peripheral edge is connected to the frame portion 8 are obtained. Also, a work-in-process substrate assembly 2A with which the cavity 5 is not formed is obtained.

Next, as shown in FIG. 5G and FIG. 6G, an adhesive is coated on a surface of the protective substrate 3 that faces the work-in-process substrate assembly 2A and the protective substrate 3 is fixed to the work-in-process substrate assembly 2A.

Next, as shown in FIG. 5H, rear surface grinding for thinning the silicon substrate 32 is performed. That is, the silicon substrate 32 is thinned by the silicon oxide film 31 and the silicon substrate 32 being polished from a surface of the silicon oxide film 31 at an opposite side to the silicon substrate 32.

Lastly, a resist mask (not shown) having an opening corresponding to a formation planned region of a cavity main body 51 is formed on a rear surface (−Z side surface) side of the silicon substrate 32. The silicon substrate 32 is etched from the rear surface using the resist mask as a mask. The transducer 1 shown in FIG. 1 to FIG. 4 is thereby obtained.

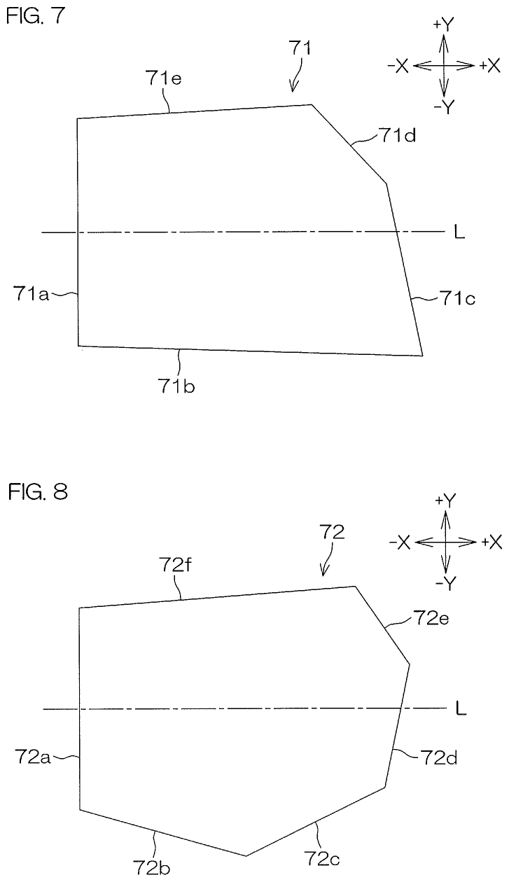

FIG. 7 to FIG. 9 are enlarged illustrative plan views showing modification examples of the vibrating film.

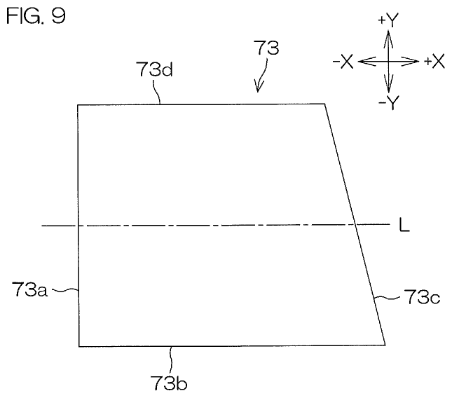

A vibrating film 71 shown in FIG. 7 has a pentagonal shape having five sides 71a to 71e in plan view. The side 71a is a connection portion connected to a supporting body. A vibrating film 72 shown in FIG. 8 has a hexagonal shape having six sides 72a to 72f in plan view. The side 72a is a connection portion connected to a supporting body. A vibrating film 73 shown in FIG. 9 has a quadrilateral shape having four sides 73a to 73d in plan view. The side 73a is the connection portion connected to the supporting body.

The vibrating films 71, 72, and 73 shown in FIG. 7, FIG. 8, and FIG. 9 respectively have non-line-symmetrical shapes with respect to the straight lines L that extend along front surfaces of the vibrating films 71, 72, and 73 and are orthogonal to lines joining both ends of the connection portions 71a, 72a, and 73a.

The five sides 71a to 71e of the vibrating film 71 shown in FIG. 7 do not include sides that are parallel to each other. Similarly, the six sides 72a to 72f of the vibrating film 72 shown in FIG. 8 do not include sides that are parallel to each other. On the other hand, the vibrating film 73 shown in FIG. 9 includes two sides 73b and 73d that are parallel to each other.

The vibrating film 7 suffices to have a non-line-symmetrical shape with respect to the straight line L that is orthogonal to the line joining both ends of the connection portion 7a and is not restricted to the shapes indicated in the preferred embodiment and modification examples described above. For example, the connection portion 7a of the vibrating film 7 may have a shape that is curved in plan view. Also, an outer edge of the vibrating film 7 excluding the connection portion 7a may have a portion that is curved in plan view.

Although with the preferred embodiment described above, a case where the transducer 1 is used as a speaker was described, the transducer 1 can also be used as a microphone that detects sound waves.

While preferred embodiments of the present disclosure were described in detail above, these are merely specific examples used to clarify the technical contents of the present disclosure and the present disclosure should not be interpreted as being limited to these specific examples and the scope of the present disclosure is limited only by the appended claims.

1. A transducer comprising:
a supporting body that has a cavity;
a vibrating film that is provided facing the cavity and capable of vibrating in the facing direction; and
a piezoelectric element at least a portion of which is formed on a front surface of the vibrating film at an opposite side to the cavity; and
wherein the vibrating film has, at a portion of an outer peripheral edge of the vibrating film, a connection portion connected to the supporting body and the vibrating film has a non-line-symmetrical shape with respect to a straight line that extends along the front surface of the vibrating film and is orthogonal to a line joining both ends of the connection portion.

2. The transducer according to claim 1, wherein the outer peripheral edge of the vibrating film does not include parallel rectilinear portions that face and are parallel to each other in plan view.

3. The transducer according to claim 2, wherein the vibrating film is, in plan view, of a polygonal shape having a plurality of sides and the plurality of sides do not include sides that face and are parallel to each other.

4. The transducer according to claim 1, wherein the supporting body includes
a supporting substrate that has the cavity and
a frame portion that is formed on the supporting substrate and is formed such as to surround the cavity,
the connection portion of the vibrating film is connected to the frame portion, and
a slit that is in communication with the cavity is formed between the frame portion and an outer peripheral edge of the vibrating film excluding the connection portion.

5. The transducer according to claim 1, wherein a cantilever is formed that includes the vibrating film and a portion of the piezoelectric element disposed on the vibrating film and has a fixed end and a free end.

6. The transducer according to claim 1, wherein the piezoelectric element includes a lower electrode at least a portion of which is disposed on the vibrating film, a piezoelectric film that is formed on the lower electrode, and an upper electrode that is formed on the piezoelectric film.

7. The transducer according to claim 6, comprising:
a hydrogen barrier film that covers the front surface of the vibrating film and a front surface of the piezoelectric element;
an interlayer insulating film that is selectively formed on the hydrogen barrier film;
an upper wiring that is formed on the interlayer insulating film and has one end connected to the upper electrode and another end extending to an outside of the cavity;
a lower wiring that is formed on the interlayer insulating film and has one end connected to the lower electrode and another end extending to the outside of the cavity; and
a passivation film that is formed on the interlayer insulating film and covers the upper wiring and the lower wiring.

8. The transducer according to claim 5, comprising: a protective substrate that is fixed to the supporting body such as to cover at least a portion of the cantilever.

9. A method for manufacturing transducer comprising:
a step of forming a piezoelectric element on a vibrating film formation layer that is formed on a supporting substrate;
a vibrating film forming step of forming a slit penetrating through the vibrating film formation layer in a thickness direction to form, in the vibrating film formation layer, a vibrating film and a frame portion that surrounds the vibrating film and with which a portion is connected to a portion of the vibrating film; and
a step of etching the supporting substrate from a cavity formation planned region of a rear surface of the supporting substrate that is a surface at an opposite side to the vibrating film formation layer to form, in a region facing the vibrating film, a cavity that is in communication with the slit; and
wherein if the portion of the vibrating film connected to the frame portion is a connection portion, the vibrating film formed in the vibrating film forming step has a non-line-symmetrical shape with respect to a straight line that extends along a front surface of the vibrating film and is orthogonal to a line joining both ends of the connection portion.

10. The method for manufacturing transducer according to claim 9, wherein an outer peripheral edge of the vibrating film does not include parallel rectilinear portions that face and are parallel to each other in plan view.

11. The method for manufacturing transducer according to claim 10, wherein the vibrating film is, in plan view, of a polygonal shape having a plurality of sides and the plurality of sides do not include sides that face and are parallel to each other.

12. The transducer according to claim 2, wherein the supporting body includes
a supporting substrate that has the cavity and
a frame portion that is formed on the supporting substrate and is formed such as to surround the cavity,
the connection portion of the vibrating film is connected to the frame portion, and
a slit that is in communication with the cavity is formed between the frame portion and an outer peripheral edge of the vibrating film excluding the connection portion.

13. The transducer according to claim 3, wherein the supporting body includes
a supporting substrate that has the cavity and
a frame portion that is formed on the supporting substrate and is formed such as to surround the cavity,
the connection portion of the vibrating film is connected to the frame portion, and
a slit that is in communication with the cavity is formed between the frame portion and an outer peripheral edge of the vibrating film excluding the connection portion.

14. The transducer according to claim 2, wherein a cantilever is formed that includes the vibrating film and a portion of the piezoelectric element disposed on the vibrating film and has a fixed end and a free end.

15. The transducer according to claim 3, wherein a cantilever is formed that includes the vibrating film and a portion of the piezoelectric element disposed on the vibrating film and has a fixed end and a free end.

16. The transducer according to claim 4, wherein a cantilever is formed that includes the vibrating film and a portion of the piezoelectric element disposed on the vibrating film and has a fixed end and a free end.

17. The transducer according to claim 12, wherein a cantilever is formed that includes the vibrating film and a portion of the piezoelectric element disposed on the vibrating film and has a fixed end and a free end.

18. The transducer according to claim 13, wherein a cantilever is formed that includes the vibrating film and a portion of the piezoelectric element disposed on the vibrating film and has a fixed end and a free end.

19. The transducer according to claim 2, wherein the piezoelectric element includes a lower electrode at least a portion of which is disposed on the vibrating film, a piezoelectric film that is formed on the lower electrode, and an upper electrode that is formed on the piezoelectric film.

20. The transducer according to claim 3, wherein the piezoelectric element includes a lower electrode at least a portion of which is disposed on the vibrating film, a piezoelectric film that is formed on the lower electrode, and an upper electrode that is formed on the piezoelectric film.
